(19) United States
(12) Patent Application Publication
(10) Pub. No.: US 2009/0165996 A1
(43) Pub. Date: Jul. 2, 2009

(54) RETICULATED HEAT DISSIPATION WITH COOLANT

(76) Inventor: Thomas W. Lynch, Galveston, TX (US)

Correspondence Address: DORSEY & WHITNEY LLP;INTELLECTUAL PROPERTY DEPARTMENT, SUITE 3400, 1420 FIFTH AVENUE, SEATTLE, WA, 98101, US

(21) Appl. No.: 11/964,524

(22) Filed: Dec. 26, 2007

(51) Int. Cl. F28F 7/00; H05K 13/04

(52) U.S. Cl. 165/80.3; 29/729

(57) ABSTRACT

Embodiments described herein may include example embodiments of methods, apparatuses, devices, and/or systems for heat dissipation with coolant.

### BACKGROUND

As the circuit density of microelectronic components increases, heat generated by these devices may typically increase as well. Microelectronic components may include, for example, microprocessors, such as central processing units (CPU), graphics processing units (GPU), digital signal processors (DSP); one or more memory devices; one or more application specific integrated circuits (ASIC); and/or other types of electronic components such as capacitors and/or resistors, as just a few examples. Microelectronic components may include an integrated circuit located within a bath-tub recess in a package. Such integrated circuits may be thermally and mechanically coupled to the package on one side, such as by a gold eutectic compound, for example. The reverse side of the integrated circuit may be temporarily left open. Pads may be placed around the edge of the integrated circuit and tiny bonding wires may be attached from the pads to the package. After bonding is complete, a cap may typically be placed over the opening of the bath tub recess in order to protect the bonding wires.

Various techniques may typically be used to remove or dissipate heat generated by a microelectronic component. These techniques may include passive and/or active thermal solutions, for example. One such technique, which may be classified as a passive thermal solution, may involve the use of a thermally conductive device in thermal contact with a microelectronic component. Such a thermally conductive device may comprise a mass of thermally conductive material such as a slug or heat spreader, or may comprise a device configured to enhance convective heat transfer, such as a heat sink. However, techniques for heat dissipation and/or removal may not produce the desired results, and additional techniques and/or devices for dissipating and/or removing heat may be used.

For example, a heat sink may be bonded to an integrated circuit package. This may typically be done by a systems manufacturer who bought the packaged integrated circuit from an integrated circuit vendor. Alternatively, the integrated circuit vendors may sell packaged integrated circuits with heat sinks already attached. The heat sink may be bolted or bonded to the package, and heat transfer compound may be placed on the integrated circuit and/or heat sink before the bonding in order to facilitate the thermal conductivity between the integrated circuit and the heat sink. Sometimes, the package body itself may be expected to radiate sufficient heat, and a separate heat sink may not be included. Typically, the heat flow through a heat sink may be a function of f(T_{bonded}−Tₒₚₑₙ) where Tₒₚₑₙ is the temperature of open side of the heat sink, and T_{bonded} is the temperature at the bonded side. As Tₒₚₑₙ decreases, heat flow significantly increases, and thus T_{bonded} may also decrease. For this reason some manufacturers may place fans directly on the heat sink to cause Tₒₚₑₙ to drop near T_{ambient}, the ambient temperature of the assembly.

The whole assembly of a heat sink and an integrated circuit package may then be placed on a system board. By definition, the entity that places the assembly on the system board is the systems manufacturer. It is not unheard of for integrated circuit vendors to also be systems manufacturers. In some systems, there may be multiple integrated circuits on the board, with the possibility of daughter boards. One or more of the integrated circuits may have heat sinks. Once the assembly has been placed on the system board, the system board may then in turn be placed in an enclosure. The enclosure may trap heat, causing T_{ambient} to rise, and then consequently causing Tₒₚₑₙ to rise, and then T_{bonded} to rise. If the T_{bonded} rises too far, the integrated circuit may melt and be destroyed. In order to lower T_{ambient} within the enclosure, some manufacturers may place fans on the enclosure. This may cause T_{ambient} to drop towards Tᵣₒₒₘ, the temperature in the room where the enclosed computer is being used.

Many variations on the conventional approach may be used. For example, a system may be used where the system boards may be immersed directly in Freon coolant. Yet other examples may include having electronic transport devices, which may move heat along with electrons, to electronically pump heat from a package.

Additionally, stacked packaging may be used for multi chip carriers. Consider the single inline packaging and mounting technique that may be used with memory chips. In this case all of the legs for a packaged memory chip may extend from one side. In this case, the chips may be mounted side by side on a board in a manner that may cause the populated board to be taller, though it may require less real estate than had such chips been mounted flat on the board. Unfortunately, this may exacerbate cooling problems, because heat may tend to gather in the areas between the chips.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1 is a front view illustrating an electronic assembly in accordance with one or more embodiments.

FIG. 2 is a side view illustrating an electronic assembly in accordance with one or more embodiments.

FIG. 3 is a side view illustrating a fin plate in accordance with one or more embodiments.

FIG. 4 is a side view illustrating a fin plate in accordance with one or more embodiments.

FIG. 5 is a top cross-sectional view taken along line 5-5 of FIG. 1 illustrating an electronic assembly in accordance with one or more embodiments.

FIG. 6 is an exploded perspective view illustrating a fin plate in accordance with one or more embodiments.

FIG. 7 is a side view illustrating an electronic assembly in accordance with one or more embodiments.

FIG. 8 is a side view illustrating an electronic assembly in accordance with one or more embodiments.

FIG. 9 is a flow diagram illustrating an example procedure in accordance with one or more embodiments.

FIG. 10 is a schematic diagram of an example computing platform in accordance with one or more embodiments.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized and structural and/or logical changes may be made without departing from the scope of claimed subject matter. It should also be noted that directions and references, for example, up, down, top, bottom, and so on, may be used to facilitate the discussion of the drawings and are not intended to restrict the application of claimed subject matter. Therefore, the following detailed description is not to be taken in a limiting sense and the scope of claimed subject matter defined by the appended claims and their equivalents.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail.

In the following description and/or claims, the term “and/or” as referred to herein may mean “and”, it may mean “or”, it may mean “exclusive-or”, it may mean “one”, it may mean “some, but not all”, it may mean “neither”, and/or it may mean “both”, although the scope of claimed subject matter is not limited in this respect.

Reference throughout this specification to “one embodiment” or “an embodiment” means that a particular feature, structure, or characteristic described in connection with the embodiment is included in at least one embodiment of claimed subject matter. Thus, the appearances of the phrase “in one embodiment” and/or “an embodiment” in various places throughout this specification are not necessarily all referring to the same embodiment. Furthermore, the particular features, structures, and/or characteristics may be combined in one or more embodiments.

An electronic assembly may comprise one or more electronic components coupled to a substrate, and may additionally be referred to as an electronic package, for example. The substrate, in at least one embodiment, may comprise a printed circuit board (PCB), for example, and may be comprised of one or more layers, which may be laminated layers, for example, and may include conductive and/or non-conductive layers, and one or more layers may have one or more conductive features formed thereon, for example. In one embodiment, a PCB may comprise one or more layers of non-conductive material interleaved and/or laminated with one or more conductive circuit patterns and/or one or more additional layers, for example. Additionally, an electronic assembly or electronic package may comprise one or more microelectronic components, including, for example, integrated circuit (IC) components such as one or more microprocessors, graphics processing units (GPU), digital signal processors (DSP) and/or a central processing units (CPU), one or more memory devices, one or more application specific integrated circuits (ASIC), and/or may include other types of electronic components such as capacitors, resistors, and/or connectors including input/output (I/O) connectors for coupling to external circuitry, such as bus circuitry, for example, but it is important to note that claimed subject matter is not so limited. In at least one embodiment, one or more electronic assemblies may be coupled to form an electronic device. Examples of electronic devices may include, for example, computers, including desktop computers, laptop computers, servers, switches, and/or hubs, handheld devices, including digital cameras and cellular or wireless telephones, and may additionally include peripheral devices, including printers, monitors, and/or scanners, for example. Those skilled in the art will recognize, however, that particular embodiments are not limited in this respect, but may be applicable to any electronic assembly and/or electronic device that utilizes one or more microelectronic components, for example.

As alluded to previously, a microelectronic component may generate heat, and a thermal solution may be utilized to at least partially dissipate the generated heat, for example. A thermal solution may comprise one or more heat dissipation devices, and may generally be classified as active and/or passive thermal solutions. In this context, active thermal solutions may refer generally to heat dissipation devices wherein at least a portion of the heat dissipation device utilizes energy to at least partially dissipate heat, such as electrical energy, chemical energy, and/or fluid energy, for example. Although claimed subject matter is not so limited, one or more active thermal solutions may comprise fans, refrigeration components, and/or thermoelectric components, also referred to as Peltier devices, as just a few examples. Additionally, passive solutions may refer generally to heat dissipation devices wherein heat dissipation is performed primarily by one or more heat transfer modes, such as conduction and/or convection, and without the use of additional energy, for example.

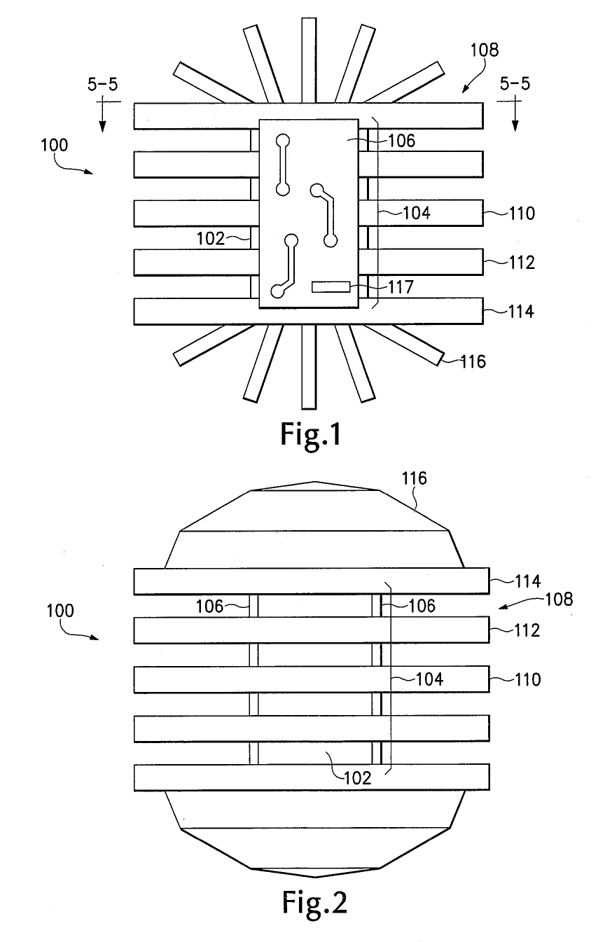

Referring now to FIG. 1, there is illustrated a front view of an electronic assembly, in accordance with at least one embodiment. An electronic assembly 100 may comprises one or more microelectronic components 102 coupled to a substrate 106. Substrate 106 may comprise a PCB, for example, and may be comprised of one or more conductive and/or nonconductive layers (not shown), which may be laminated, for example. In such an arrangement, substrate 106 may be made of phranelic material, fiber glass material, mylar tape, or the like. None of these materials is well suited for heat conduction; accordingly, a majority of the heat may be expected to radiate from microelectronic components 102, and not from substrate 106. Substrate 106 may be coupled to one or more microelectronic components 102, which may comprise one or more types of microelectronic components, as described previously. For example, microelectronic component 102 may comprise an integrated circuit, such as a CPU, for example, located within a package; alternatively, microelectronic component 102 may comprise a raw die without a separate package.

Two or more microelectronic components 102 may be oriented and arranged to comprise an electronic stack 104. For example, microelectronic components 102 may be coupled to substrate 106 by use of one or more pins and/or the like. For example, microelectronic components 102 may be coupled to substrate 106 by use of various techniques, such as, for example, dual inline packaging, single inline packaging, and wire bonding, although, again, these are just examples, and claimed subject matter is not limited in this respect, and may be applicable to any microelectronic component and/or attachment method resulting in the formation of an electronic assembly comprising at least one microelectronic component capable of generating heat, for example. Dual inline package and/or single inline package microelectronic components 102 may comprise ceramic packages, epoxy packages, and/or packages formed of other materials.

In instances where microelectronic components 102 may be coupled to substrate 106 by use of dual inline packaging, microelectronic components 102 may be attached between a pair of substrates 106, such as is illustrated in FIG. 2. In such a case, the pair of substrates 106 may be located in spaced parallel alignment with respect to one another while microelectronic components 102 may be located to extend substantially perpendicular to the pair of substrates 106 with legs of the dual inline packaging bent straight out. Further, some of the dual inline package microelectronic components 102 may contain wiring cross bridges in addition to containing integrated circuits, where the wiring cross bridges may pass between the pair of substrates 106. Alternatively, some of the dual inline package microelectronic components 102 may not hold integrated circuits at all, and may rather only contain wiring bridges. Additionally, some of the dual inline package microelectronic components 102 may hold yet other items, such as hybrid circuits, multichip modules, components such as capacitors, load resistors, choke coils, transforms, and/or the like.

Referring back to FIG. 1, likewise, in instances where microelectronic components 102 may be coupled to substrate 106 by use of single inline packaging, microelectronic components 102 may be attached to a single substrate 106. In such a case, microelectronic components 102 may be located to extend substantially perpendicular to the single substrate 106. Further, use of single inline package microelectronic components 102 instead of dual inline packages may eliminate the need for a bridge passing between multiple substrates 106.

Alternatively, microelectronic components 102 may be tape-mounted instead of using dual inline packages or single inline packages. For example, such tape-mounted microelectronic components 102 may connect to a single substrate 106 and run perpendicular from the single substrate 106, similar to the arrangement of substrate 106 for single inline packages, as discussed above. Alternatively, such tape-mounted microelectronic components 102 may connect between a pair of substrates 106 and run perpendicular between the pair of substrates 106, similar to the arrangement of substrates 106 for dual inline packages, as discussed above.

A heat dissipation device 108 may be coupled to one or more microelectronic components 102. Heat dissipation device 108 may comprise one or more fin plates 110 coupled to one or more microelectronic components 102. As used herein, the term “fin plate” may mean a portion of heat dissipation device 108 capable of heat dissipation. Fin plates 110 may be formed of aluminum and/or other heat conductive materials. Fin plates 110 may be located to extend substantially perpendicular to the substrate 106 between the microelectronic components 102. For example, in instances where microelectronic components 102 comprise dual inline packages, these dual inline package microelectronic components 102 may be stacked alternately with fin plates 110, so that the legs of microelectronic components 102 may stick out the front or back of electronic stack 104 and so that fin plates 110 may pass through electronic stack 104 from side to side. In other words, fin plates 110 may run askew of substrates 106.

Additionally, heat dissipation device 108 may be coupled to one or more of the microelectronic components 102 by use of one or more adhesive materials, and/or one or more mechanical fastener mechanisms such as clamps and/or pins (not shown), for example. It is important to note, however, that numerous configurations of a heat dissipation device as well as numerous methods of attachment may be utilized, and claimed subject matter is not limited in this respect. For example, multiple microelectronic components 102 may be held together at least in part via bolts and/or other fasteners that may run lengthwise through electronic stack 104 of microelectronic components 102 and/or that may run through the fin plates 110. Additionally or alternatively, a thermally conductive material (not shown) may be located between heat dissipation device 108 and microelectronic components 102. Such a thermally conductive material may comprise a chemical bonding compound capable of directly attaching heat dissipation device 108 to microelectronic components 102. In such a case, electronic stack 104 of microelectronic components 102 may be held together at least in part via heat transfer material used to bond fin plates 110 to microelectronic components 102.

Fin plates 110 may be of uniform design and/or may vary in design based at least in part on the location of the fin plates 110 with respect to the electronic stack 104 of microelectronic components 102. For example, fin plates 110 may comprise one or more interior fin plates 112 located between a pair of adjacent microelectronic components 102 and may be positioned parallel with respect to the microelectronic components 102 of electronic stack 104. Additionally or alternatively, fin plates 110 may comprise one or more cap fin plates 114 located at a top and/or bottom microelectronic component 102 of electronic stack 104 and may be positioned parallel with respect to microelectronic components 102 of electronic stack 104. Additionally or alternatively, fin plates 110 may comprise one or more end fin plates 116 located adjacent a top and/or bottom surface of electronic stack 104 and positioned non-parallel with respect to a top and/or bottom surface of the electronic stack 104.

Additionally or alternatively, electronic assembly 100 may be placed in an enclosure (not shown). Such an enclosure may have a fan (not shown) that blows air through heat dissipation device 108. Alternatively, electronic assembly 100 may constitute its own enclosure. For large installations, edges of fin plates 110 may be secured to a rack mount frame. Alternatively, a standalone electronic assembly 100 may have flats (not shown) in fin plates 110 capable of supporting electronic assembly 100 on a surface of a desk or floor.

Additionally or alternatively, one or more connectors 117 may be present on substrate 106 and/or may be present on fin plates 110. Connectors 117 may be capable of attaching electronic stack 104 to other stacks and/or other electronic equipment. Connectors 117 may couple electronic assembly 110 with other stacks or other electronic equipment through ribbon, wire, and/or the like running from connectors 117.

In operation, although claimed subject matter is not so limited, a heat efficient reticulated packaging, such as for example heat dissipation device 108, may be utilized to provide an increased heat transfer. Often, conventional packaging and system board manufacturing may be set up for only for building on large flat boards. Often conventional thermal solutions may suffer from a common drawback; the system board may remain a large flat object. For example, a substrate, such as a system board, may only have a single radiating surface. In contrast, a reticulated surface, such as for example heat dissipation device 108, may have numerous radiating surfaces, potentially providing an increased heat transfer.

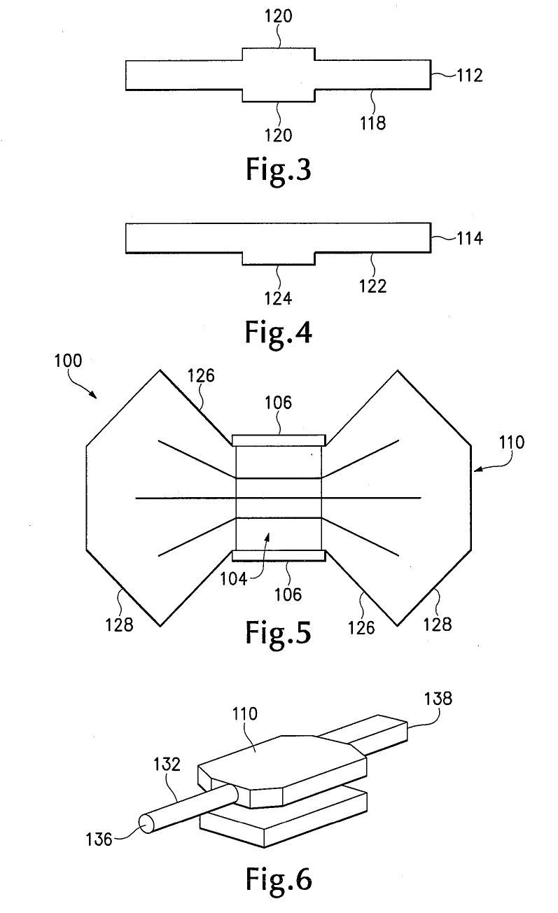

Referring now to FIG. 3, there is illustrated a side view of a fin plate, in accordance with at least one embodiment. Interior fin plates 112 may comprise a substantially planar extension surface 118 extending outside of electronic stack 104. Additionally or alternatively, interior fin plates 112 may comprise one or more bearing surfaces 120 extending from extension surface 118. Bearing surfaces 120 may be capable of being thermally coupled to at least one of the microelectronic components 102, such as for example, coupled between a pair of adjacent microelectronic components 102. In instances where tape-mounted microelectronic components 102 may be used, heat transfer material may stand between the bearing surface 120 and microelectronic components 102, although, of course, claimed subject matter is not limited in this respect.

Referring now to FIG. 4, there is illustrated a side view of a fin plate, in accordance with at least one embodiment. Cap fin plates 114 may comprise a substantially planar extension surface 122 extending outside of electronic stack 104. Additionally or alternatively, cap fin plates 114 may comprise one or more bearing surfaces 124 extending from extension surface 122. Bearing surfaces 124 may be capable of being thermally coupled to at least one of the microelectronic components 102, such as for example, coupled to a top and/or bottom microelectronic component 102 of electronic stack 104. In instances where tape-mounted microelectronic components 102 may be used, only heat transfer material may stand between the bearing surface 124 and microelectronic components 102.

Referring now to FIG. 5, there is illustrated a top cross-sectional view of an electronic assembly taken along line 5-5 of FIG. 1, in accordance with at least one embodiment. As illustrated, when looking from the top of electronic assembly 100, fin plates 110 may narrow so that they may pass through the pair of substrates 106. Likewise, fin plates 110 may widen external to electronic stack 104 for an increased heat transfer area. For example, fin plate 110 may comprise a pair of concave edges 126 located adjacent the pair of substrates 106. As used herein, the term concave may mean a curved surface and/or a series of straight surfaces joined together comprising at least one interior angle greater than 180 degrees, although the scope of claimed subject matter may not be limited in this respect. Additionally or alternatively, fin plate 110 may comprises a pair of convex edges 128 extending outside of electronic stack 104. As used herein the term convex may mean a curved surface and/or a series of straight surfaces joined together comprising at least one interior angle less than 180 degrees, although the scope of claimed subject matter may not be limited in this respect. Additionally or alternatively, fin plate 110 may comprise any number of alternative shapes. For example, fin plate 110 may comprise a generally rectangular shape. In such a case, fin plate 110 may comprise portions generally rectangular extending outside of electronic stack 104 in a bar form of constant width.

Additionally or alternatively, as discussed above, in instances where microelectronic components 102 may be coupled to substrate 106 by use of single inline packaging, microelectronic components 102 may be attached to a single substrate 106. In such a case, use of single inline package microelectronic components 102 instead of dual inline packages may increase the available surface area of fin plates 110, and may increase heat dissipation efficiency. For example, fin plate 110 may comprise a single concave edge located adjacent the single substrate 106. Additionally or alternatively, fin plate 110 may comprises a single convex edge extending outside of electronic stack 104 and positioned opposite the single concave edge. Additionally or alternatively, fin plate 110 may comprise any number of alternative shapes. For example, fin plate 110 may comprise a generally rectangular shape. In such a case, fin plate 110 may comprise generally rectangular portions extending outside of electronic stack 104.

Referring now to FIG. 6, there is illustrated an exploded perspective view of a fin plate, in accordance with at least one embodiment. As illustrated, one or more of fin plates 110 may further comprise a coolant conduit 132 located within one or more of fin plates 110 and capable of passing coolant within one or more of fin plates 110. An inlet 136 may be coupled to coolant conduits 132. Inlet 136 may be capable of passing coolant to fin plate 110 through coolant conduit 132. An outlet 138 may be coupled to coolant conduit 132. Outlet 138 may be capable of passing coolant from fin plate 110. In such a case, fin plate 110 may operate to remove heat from one or more microelectronic components 102 at least in part by passing coolant through coolant conduit 132 from inlet 136 to outlet 138.

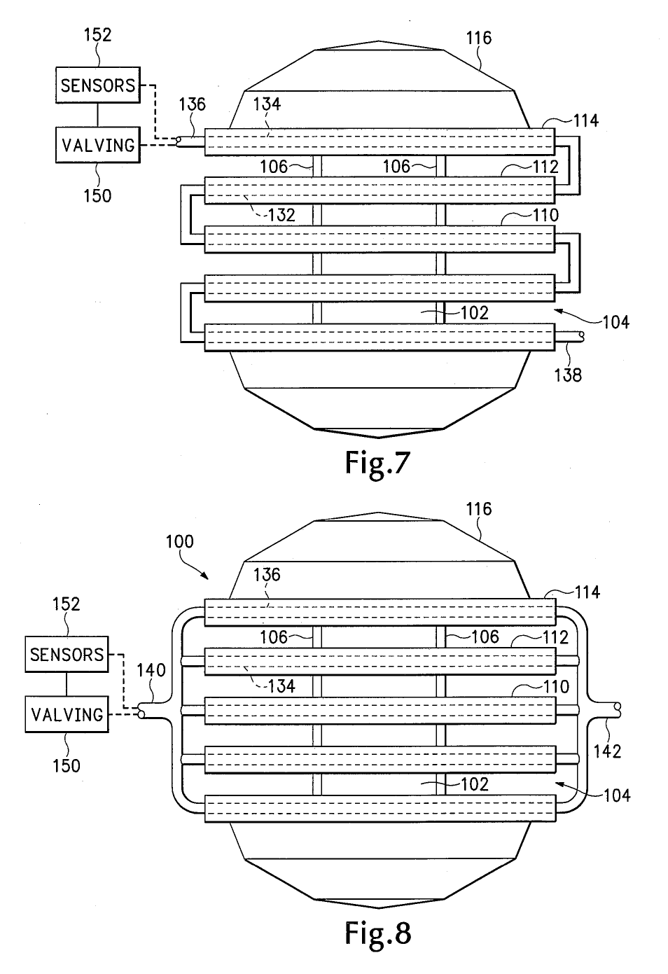

Referring now to FIG. 7, there is illustrated a side view of an electronic assembly, in accordance with at least one embodiment. As illustrated, one or more of fin plates 110 may further comprise a coolant conduit 132 located within one or more of fin plates 110 and capable of passing coolant within one or more of fin plates 110. For example, fin plate 112 may comprise coolant conduit 132 located therein while fin plate 114 may comprise coolant conduit 134 located therein. An inlet 136 may be coupled to at least one of coolant conduits 132 and 134. Inlet 136 may be capable of passing coolant to fin plates 110 through coolant conduits 132 and 134. An outlet 138 may be coupled to at least one of coolant conduits 132 and 134. Outlet 138 may be capable of passing coolant from fin plates 110. In such a case, heat dissipation device 108 may be capable of passing coolant through coolant conduits 132 and 134 in series from inlet 136 to outlet 138. For example, the entry point and exit point for coolant into a given fin plate 110 may change as one walks down electronic assembly 100. One such pattern may have the entry and exit pipes to remain reciprocal on coolant conduit 132, but for the entry point to rotate 30 degrees, or the like, for the next coolant conduit 134. Such rotation of coolant conduits 132 and 134 may continue down electronic assembly 100 in a uniform or non-uniform manner. Such rotation of coolant conduits 132 and 134 may be done purely for mechanical reasons. For example, microelectronic components 102 squeezed in electronic assembly 100 may be very thin, and it may be problematic to stack all the entrance and exit pipes in the same line.

Such a coolant conduit 132 located within one or more of fin plates 110 may include internal channeling (not shown). Such internal channeling may be utilized in order to increase the time the coolant remains in fin plate 110. For example, coolant conduits 132 and/or 134 may carry a heat transfer liquid, such as cooling water. As the coolant moves through fin plate 110 it may become warmer. It may take more warm coolant to remove the same amount of heat as for cooler coolant; hence the internal channeling and the shape of fin plate 110 may be varied so that the coolant may flow faster over the more distant and/or warmer areas in fin plate 110.

Other various types of coolant may be utilized in fin plate 110. For example, an evaporative coolant may be utilized. In instances where an evaporative coolant may be used, evaporation rates may often change as micro droplets of such an evaporative coolant become smaller and the density of evaporating coolant changes. As the density of evaporating coolant changes the total evaporative area summed over the droplets may also change. In such a case, internal channeling may be utilized in order to compensate for this effect by causing the coolant pressure to drop as the coolant travels through fin plate 110. In operation, coolant conduits 132 and/or 134 may constitute the pipes of an evaporator for a cooling system. Such a cooling system may compress a coolant, such as Freon and/or the like, in a setting of narrow pipes that are embedded in a radiator structure. This radiator structure may be referred to as a condenser. The output of the condenser may lead to a set of pipes with larger cross section. In this area of larger cross section the coolant may expand. As the coolant expands it may absorb heat. Such an area pipes with larger cross section may be referred to as an evaporator. The output of the evaporator may then lead to a compressor pump (not shown) which once again may force coolant through the condenser. Here, coolant conduits 132 and/or 134 may be oriented and arranged to be capable of operation as an evaporator.

Referring now to FIG. 8, there is illustrated a side view of an electronic assembly, in accordance with at least one embodiment. As illustrated, one or more of fin plates 110 may further comprise a coolant conduit 132 located within one or more of fin plates 110 and capable of passing coolant within one or more of fin plates 110. For example, fin plate 112 may comprise coolant conduit 132 located therein while fin plate 114 may comprise coolant conduit 134 located therein. An inlet manifold 140 may be coupled to two or more fin plates 110. Inlet manifold 140 may be capable of passing coolant to two or more fin plates 110. Similarly, an outlet manifold 142 may be coupled to two or more fin plates 110. Outlet manifold 142 may be capable of passing coolant from two or more fin plates 110. In such a case, heat dissipation device 108 may be capable of passing coolant within two or more fin plates 110 in parallel from inlet manifold 140 to outlet manifold 142.

For example, multiple levels of manifolds may be used in large systems. A main manifold may sits behind a rack mount (not shown) and may connect to a coolant feed exiting from a facilities industrial chiller, for example. Secondary manifolds may be used to couple to multiple individual electronic devices 100.

Additionally or alternatively, an electronic assembly 100 as described above in FIGS. 7 and 8 may optionally include valving 150 associated with one or more coolant conduits 132 and/or 134; associated with one or more coolant inlets 136 and/or outlets 138; and/or associated with one or more inlet manifolds 140 and/or outlet manifolds 142. Such valving 150 may be utilized to control the flow of coolant through the entire electronic assembly 100 and/or to control the flow of coolant through portions of an electronic assembly 100 by either turning flow on, flow off, and/or adjusting coolant flow rates. For example, microelectronic components 102 near the center of an electronic assembly 100 may operate at higher temperatures than other microelectronic components 102 in an electronic assembly 100. In such a case, such valving 150 as described above may be operated so that microelectronic components 102 near the center of an electronic assembly 100 may be provided with an increased flow of coolant via adjacent fin plates 110 to maintain a more even cooling across electronic assembly 100.

Additionally or alternatively, an electronic assembly 100 as described above in FIGS. 7 and 8 may optionally include sensors 152 associated with an electronic assembly 100 and/or valving 150. Such sensors 152 may be utilized to monitor the conditions of the electronic assembly 100 and/or valving 150. For example, sensors 152 may comprise heat sensors capable of monitoring the temperature levels of various microelectronic components 102 within electronic assembly 100. Such sensors 152 may be operated to provide information regarding local hot spots among microelectronic components 102 of an electronic assembly 100. In such a case, information from sensors 152 may be utilized in determining adjustments to valving 150 so as to provide with an increased flow of coolant to local hot spots in order to maintain a more even cooling across electronic assembly 100.

Additionally or alternatively, an electronic assembly 100 as described above in FIGS. 7 and 8 may be supplied with coolant from various sources. For example, such coolant may come from a cold water distribution for an air conditioning system. Such an air conditioning system may include a cooling tower for receiving the outlet coolant from electronic assembly. Utilization of coolant from such an air conditioning system may provide a reduced noise level near electronic assembly 100 as compared to fan-type coolant systems.

Additionally or alternatively, an electronic assembly 100 as described above in FIGS. 7 and 8 may be utilized to provide multiple individual stacks of electronic assembly 100 associated together. Additionally or alternatively, an electronic assembly 100 as described above in FIGS. 7 and 8 may comprise a small scale heat dissipation device 108 that may be utilized for various cooling applications. For example, such a small scale heat dissipation device 108 may be used as a substitute and/or augmentation for a fan-type coolant system on a media drive, such as for example a disk drive.

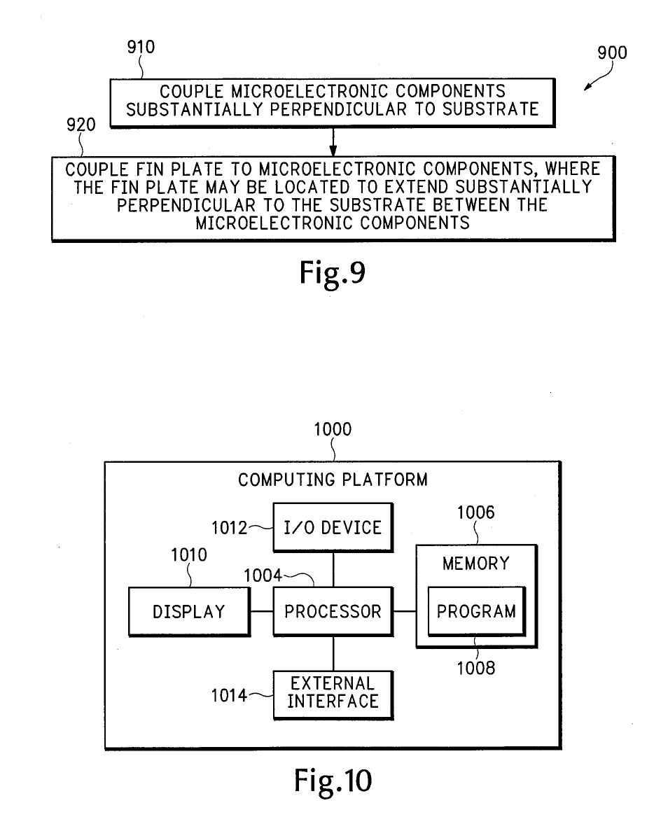

Referring to FIG. 9, a flow diagram illustrates an example procedure of making one or more of the aforementioned devices and/or assemblies, although the scope of claimed subject matter may not be limited in this respect. Procedure 900 is illustrated in FIG. 9 with a number of blocks that and may be used to manufacture one or more of the aforementioned devices and/or assemblies. Additionally, although procedure embodiment 900, as shown in FIG. 9, comprises one particular order of blocks, the order in which the blocks are presented does not necessarily limit claimed subject matter to any particular order. Likewise, intervening blocks shown in FIG. 9 and/or additional blocks not shown in FIG. 9 may be employed and/or blocks shown in FIG. 9 may be eliminated, without departing from the scope of claimed subject matter.

As illustrated, procedure embodiment 900 starts at block 910 where two or more microelectronic components 102 may be coupled substantially perpendicular to substrate 106. At block 920, fin plate 110 of heat dissipation device 108 may be coupled to the two or more microelectronic components 102, wherein fin plate 112 may comprises a coolant conduit 132 located within fin plate 112 and capable of passing coolant within fin plate 112. Fin plate 112 may be located to extend substantially perpendicular to substrate 106 between the two or more microelectronic components 102. Additionally or alternatively, a second fin plate 114 may be coupled to the two or more microelectronic components 102 and coolant conduit 132 located within fin plate 112 may be coupled to a second coolant conduit 134 located second fin plate 114 capable of passing coolant to two or more fin plates 110 in series. Similarly, a second fin plate 114 may be coupled to the two or more microelectronic components 102, where an inlet manifold 140 and an outlet 142 manifold may be coupled to the fin plates 110 to pass coolant through the fin plates 110 in parallel.

Referring to FIG. 10, a block diagram of a computing platform 1000 according to one or more embodiments is illustrated, although the scope of claimed subject matter is not limited in this respect. Computing platform 1000 may include more and/or fewer components than those shown in FIG. 10. However, generally conventional components may not be shown, for example, a battery, a bus, and so on.

One or more example embodiments described above may be employed within computing platform 1000. For example, computing platform 1000 may include an electronic assembly 100 as described above. Additionally or alternatively, computing platform 1000 may include a heat dissipation device 108 as described above. For example, computing platform 1000 may be utilized to examine the output from sensors 152 and/or adjusts the flow rate through various parts of electronic assembly 100 via valving 150 in order to control the operating temperature within electronic assembly 100.

Computing platform 1000, as shown in FIG. 10 may be utilized to embody tangibly a computer program and/or graphical user interface by providing hardware components on which the computer program and/or graphical user interface may be executed. Such a procedure, computer program and/or machine readable instructions may be stored tangibly on a computer and/or machine readable storage medium such as a compact disk (CD), digital versatile disk (DVD), flash memory device, hard disk drive (HDD), and so on. As shown in FIG. 10, computing platform 1000 may be controlled by processor 1004, including one or more auxiliary processors (not shown). Processor 1004 may comprise a central processing unit such as a microprocessor or microcontroller for executing programs, performing data manipulations, and controlling the tasks of computing platform 1000. Auxiliary processors may manage input/output, perform floating point mathematical operations, manage digital signals, perform fast execution of signal processing algorithms, operate as a back-end processor and/or a slave-type processor subordinate to processor 1004, operate as an additional microprocessor and/or controller for dual and/or multiple processor systems, and/or operate as a coprocessor and/or additional processor. Such auxiliary processors may be discrete processors and/or may be arranged in the same package as processor 1004, for example, in a multicore and/or multithreaded processor; however, the scope of the scope of claimed subject matter is not limited in these respects.

Communication with processor 1004 may be implemented via a bus (not shown) for transferring information among the components of computing platform 1000. A bus may include a data channel for facilitating information transfer between storage and other peripheral components of computing platform 1000. A bus further may provide a set of signals utilized for communication with processor 1004, including, for example, a data bus, an address bus, and/or a control bus. A bus may comprise any bus architecture according to promulgated standards, for example, industry standard architecture (ISA), extended industry standard architecture (EISA), micro channel architecture (MCA), Video Electronics Standards Association local bus (VLB), peripheral component interconnect (PCI) local bus, PCI express (PCIe), hyper transport (HT), standards promulgated by the Institute of Electrical and Electronics Engineers (IEEE) including IEEE 488 general-purpose interface bus (GPIB), IEEE 696/S-100, and so on, although the scope of the scope of claimed subject matter is not limited in this respect.

Other components of computing platform 1000 may include, for example, memory 1006, including one or more auxiliary memories (not shown). Memory 1006 may provide storage of instructions and data for one or more programs 1008 to be executed by processor 1004. Memory 1006 may be, for example, semiconductor-based memory such as dynamic random access memory (DRAM) and/or static random access memory (SRAM), and/or the like. Other semi-conductor-based memory types may include, for example, synchronous dynamic random access memory (SDRAM), Rambus dynamic random access memory (RDRAM), ferroelectric random access memory (FRAM), and so on. Alternatively or additionally, memory 1006 may be, for example, magnetic-based memory, such as a magnetic disc memory, a magnetic tape memory, and/or the like; an optical-based memory, such as a compact disc read write memory, and/or the like; a magneto-optical-based memory, such as a memory formed of ferromagnetic material read by a laser, and/or the like; a phase-change-based memory such as phase change memory (PRAM), and/or the like; a holographic-based memory such as rewritable holographic storage utilizing the photorefractive effect in crystals, and/or the like; and/or a molecular-based memory such as polymer-based memories, and/or the like. Auxiliary memories may be utilized to store instructions and/or data that are to be loaded into memory 1006 before execution. Auxiliary memories may include semiconductor based memory such as read-only memory (ROM), programmable read-only memory (PROM), erasable programmable read-only memory (EPROM), electrically erasable read-only memory (EEPROM), and/or flash memory, and/or any block oriented memory similar to EEPROM. Auxiliary memories also may include any type of non-semiconductor-based memories, including, but not limited to, magnetic tape, drum, floppy disk, hard disk, optical, laser disk, compact disc read-only memory (CD-ROM), write once compact disc (CD-R), rewritable compact disc (CD-RW), digital versatile disc read-only memory (DVD-ROM), write once DVD (DVD-R), rewritable digital versatile disc (DVD-RAM), and so on. Other varieties of memory devices are contemplated as well.

Computing platform 1000 further may include a display 1010. Display 1010 may comprise a video display adapter having components, including, for example, video memory, a buffer, and/or a graphics engine. Such video memory may be, for example, video random access memory (VRAM), synchronous graphics random access memory (SGRAM), windows random access memory (WRAM), and/or the like. Display 1010 may comprise a cathode ray-tube (CRT) type display such as a monitor and/or television, and/or may comprise an alternative type of display technology such as a projection type CRT type display, a liquid-crystal display (LCD) projector type display, an LCD type display, a light-emitting diode (LED) type display, a gas and/or plasma type display, an electroluminescent type display, a vacuum fluorescent type display, a cathodoluminescent and/or field emission type display, a plasma addressed liquid crystal (PALC) type display, a high gain emissive display (HGED) type display, and so forth.

Computing platform 1000 further may include one or more I/O devices 1012. I/O device 1012 may comprise one or more I/O devices 1012 such as a keyboard, mouse, trackball, touchpad, joystick, track stick, infrared transducers, printer, modem, RF modem, bar code reader, charge-coupled device (CCD) reader, scanner, compact disc (CD), compact disc read-only memory (CD-ROM), digital versatile disc (DVD), video capture device, TV tuner card, touch screen, stylus, electroacoustic transducer, microphone, speaker, audio amplifier, and/or the like.

Computing platform 1000 further may include an external interface 1014. External interface 1014 may comprise one or more controllers and/or adapters to provide interface functions between multiple I/O devices 1012. For example, external interface 1014 may comprise a serial port, parallel port, universal serial bus (USB) port, and IEEE 1394 serial bus port, infrared port, network adapter, printer adapter, radio-frequency (RF) communications adapter, universal asynchronous receiver-transmitter (UART) port, and/or the like, to interface between corresponding I/O devices 1012. External interface 1014 for an embodiment may comprise a network controller capable of providing an interface, directly or indirectly, to a network, such as, for example, the Internet.

In the preceding description, various aspects of claimed subject matter have been described. For purposes of explanation, specific numbers, systems and/or configurations were set forth to provide a thorough understanding of claimed subject matter. However, it should be apparent to one skilled in the art having the benefit of this disclosure that claimed subject matter may be practiced without the specific details. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all such modifications and/or changes as fall within the true spirit of claimed subject matter.

What is claimed is:

1. An apparatus comprising:
a substrate;
two or more microelectronic components coupled to the substrate; wherein the two or more microelectronic components are located to extend substantially perpendicular to the substrate; and
a heat dissipation device comprising a fin plate, wherein the fin plate is coupled to the two or more microelectronic components, and wherein the fin plate comprises a coolant conduit located within the fin plate and capable of passing coolant within the fin plate.

2. The apparatus of claim 1, wherein the heat dissipation device comprises:
two or more fin plates;
two or more coolant conduits located within the two or more fin plates and capable of passing coolant within the two or more fin plates;
an inlet coupled to at least one of the two or more coolant conduits and capable of passing coolant to the two or more fin plates in series; and
an outlet coupled to at least one of two or more coolant conduits and capable of passing coolant from the two or more fin plates.

3. The apparatus of claim 1, wherein the heat dissipation device comprises:
two or more fin plates;
two or more coolant conduits located within the two or more fin plates and capable of passing coolant within the two or more fin plates in parallel;
an inlet manifold coupled to the two or more fin plates and capable of passing coolant to the two or more fin plates; and
an outlet manifold coupled to the two or more fin plates and capable of passing coolant from the two or more fin plates.

4. The apparatus of claim 1, wherein the fin plate is located to extend substantially perpendicular to the substrate between the two or more microelectronic components.

5. The apparatus of claim 1, wherein the two or more microelectronic components comprise an electronic stack, and wherein the fin plate comprises a concave edge located adjacent the substrate and a convex edge extending outside of the electronic stack.

6. The apparatus of claim 1, further comprising:
a second substrate coupled to the two or more microelectronic components and located to position the two or more microelectronic components between the substrate and the second substrate;
wherein the two or more microelectronic components comprise an electronic stack; and
wherein the fin plate comprises:
a concave edge located adjacent the substrate,
a second concave edge located adjacent the second substrate, and
a convex edge extending outside of the electronic stack.

7. The apparatus of claim 1, wherein the two or more microelectronic components comprise an electronic stack comprising a top surface and a bottom surface, and wherein the heat dissipation device comprises one or more end fin plates with at least one fin plate located adjacent the top surface to the electronic stack and positioned non-parallel with respect to the top surface to the electronic stack.

8. The apparatus of claim 1, wherein the two or more microelectronic components comprise an electronic stack, and wherein the fin plate comprises a substantially planar extension surface extending outside of the electronic stack and a bearing surface extending from the extension surface, wherein the bearing surface is capable of being thermally coupled to at least one of the two or more microelectronic components.

9. The apparatus of claim 1, wherein the microelectronic component comprises an integrated circuit coupled to a package.

10. The apparatus of claim 1, further comprising a thermally conductive material located between the heat dissipation device and the microelectronic component.

11. An apparatus comprising:
a substrate;
two or more microelectronic components coupled to the substrate; wherein the two or more microelectronic components are located to extend substantially perpendicular to the substrate; and
a heat dissipation device comprising a fin plate, wherein the fin plate is coupled to the two or more microelectronic components, and wherein the fin plate comprises a coolant conduit located within the fin plate and capable of passing coolant within the fin plate;
a bus coupled to the microelectronic component; and
a memory device coupled to the bus.

12. The apparatus of claim 11, wherein the heat dissipation device comprises:
two or more fin plates;
two or more coolant conduits located within the two or more fin plates and capable of passing coolant within the two or more fin plates;
an inlet coupled to at least one of the two or more coolant conduits and capable of passing coolant to the two or more fin plates in series; and
an outlet coupled to at least one of two or more coolant conduits and capable of passing coolant from the two or more fin plates.

13. The apparatus of claim 11, wherein the heat dissipation device comprises:
two or more fin plates;
two or more coolant conduits located within the two or more fin plates and capable of passing coolant within the two or more fin plates in parallel;
an inlet manifold coupled to the two or more fin plates and capable of passing coolant to the two or more fin plates; and
an outlet manifold coupled to the two or more fin plates and capable of passing coolant from the two or more fin plates.

14. The apparatus of claim 1, wherein the fin plate is located to extend substantially perpendicular to the substrate between the two or more microelectronic components.

15. The apparatus of claim 11, wherein the two or more microelectronic components comprise an electronic stack, and wherein the fin plate comprises a concave edge located adjacent the substrate and a convex edge extending outside of the electronic stack.

16. The apparatus of claim 11, further comprising:
a second substrate coupled to the two or more microelectronic components and located to position the two or more microelectronic components between the substrate and the second substrate;
wherein the two or more microelectronic components comprise an electronic stack; and
wherein the fin plate comprises:
a concave edge located adjacent the substrate,
a second concave edge located adjacent the second substrate, and
a convex edge extending outside of the electronic stack.

17. The apparatus of claim 11, wherein the two or more microelectronic components comprise an electronic stack comprising a top surface and a bottom surface, and wherein the heat dissipation device comprises one or more end fin plates with at least one fin plate located adjacent the top surface to the electronic stack and positioned non-parallel with respect to the top surface to the electronic stack.

18. The apparatus of claim 11, wherein the two or more microelectronic components comprise an electronic stack, and wherein the fin plate comprises a substantially planar extension surface extending outside of the electronic stack and a bearing surface extending from the extension surface, wherein the bearing surface is capable of being thermally coupled to at least one of the two or more microelectronic components.

19. A method comprising:
coupling two or more microelectronic components substantially perpendicular to a substrate; and
coupling a heat dissipation device comprising a fin plate to the two or more microelectronic components, and wherein the fin plate comprises a coolant conduit located within the fin plate and capable of passing coolant within the fin plate.

20. The method of claim 19, further comprising:
coupling a second fin plate to the two or more microelectronic components; and
coupling the coolant conduit located within the fin plate to a second coolant conduit located the second fin plate capable of passing coolant to the two or more fin plates in series.

21. The method of claim 19, further comprising:
coupling a second fin plate to the two or more microelectronic components; and
coupling an inlet manifold to the fin plates capable of passing coolant to the fin plates in parallel; and
coupling an outlet manifold to the fin plates capable of passing coolant from the fin plates.
